(19) United States
(12) Patent Application Publication
(10) Pub. No.: US 2014/0077893 A1
(43) Pub. Date: Mar. 20, 2014

(54) SUBSTRATE INTEGRATED WAVEGUIDE COUPLER

(71) Applicant: ELECTRONICS AND TELECOMMUNICATIONS RESEARCH IN, Daejeon (KR)

(72) Inventors: Hong Yeol LEE, Chungcheongbuk-do (KR); Man Seok UHM, Daejeon (KR); So Hyeun YUN, Daejeon (KR); Chang Soo KWAK, Daejeon (KR); Jang Sup CHOI, Daejeon (KR); In Bok YOM, Daejeon (KR)

(73) Assignee: Electronics And Telecommunications Research Institute, Daejeon (KR)

(21) Appl. No.: 13/706,819

(22) Filed: Dec. 6, 2012

(30) Foreign Application Priority Data
Sep. 18, 2012 (KR) 10-2012-0103070

(51) Int. Cl. H01P 5/02

(52) U.S. Cl. CPC H01P 3/006; H03H 7/38
USPC 333/33; 333/34

(57) ABSTRACT

Disclosed is a substrate integrated waveguide coupler. The substrate integrated waveguide coupler according to the present invention includes: a substrate; an upper conducting plate applied to an upper portion of the substrate; a lower conducting plate applied to a lower portion of the substrate; two peripheral via holes disposed parallel to each other on both sides of the substrate, respectively, and being of a pipeline type electrically connecting the upper conducting plate and the lower conducting plate to each other; and an inner via hole disposed between the two peripheral via holes, and having a center thereof separated by a preset distance and forming a short slot functioning to couple input signals.

### CROSS-REFERENCE TO RELATED APPLICATIONS

This application claims priority to and the benefit of Korean Patent Application No. 10-2012-0103170 filed in the Korean Intellectual Property Office on Sep. 18, 2012, the entire contents of which are incorporated herein by reference.

### TECHNICAL FIELD

The present invention relates to a substrate integrated waveguide coupler, and particularly, to a substrate integrated waveguide coupler having pipeline type via holes formed to be disposed mutually parallel to each other at both sides of the substrate integrated waveguide coupler, and having a preset section of the pipeline type via holes formed with at least one step.

### BACKGROUND ART

A substrate integrated waveguide (SIW) is a structure in which the top surface and the bottom surface of a dielectric semiconductor are applied as a conductor, and via holes that electrically connect the conductors of both the upper and lower surfaces are disposed at regular intervals along the vertical axis walls of the waveguide. Accordingly, the SIW is a rectangular waveguide filled with a dielectric, and is completely integrated with a typical substrate, can be designed to have a thin thickness and be very light and small, and has a blocking function so as not to be affected by external electromagnetic waves. Also, because RF components can be integrated in a configuration in which the top surface and bottom surface are covered with a conductor when flat substrate technology is used, the structure is favorable for designing microwave or millimeter wave components or systems.

There is much research being actively conducted on power distributors and couplers, resonators, band pass filters, phase shifters, couplers, etc. that use the above-mentioned substrate integrated waveguide.

FIG. 1 is a diagram illustrating the structure of a substrate integrated waveguide according to the related art.

Referring to FIG. 1, a substrate integrated waveguide according to the related art is a structure in which a conducting plate is applied on a top surface 20 and a bottom surface 30 of a dielectric substrate 10, and metal cylindrical via holes 40 are disposed at regular intervals along vertical axis walls to electrically connect the conducting plates on the top surface and the bottom surface to each other.

However, this type of cylindrical via hole structure induces the occurrence of transmission loss due to a slightly leaking signal because empty spaces exist between the via holes.

### SUMMARY OF THE INVENTION

The present invention has been made in an effort to provide a substrate integrated waveguide coupler having pipeline type via holes formed to be disposed mutually parallel to each other at both sides of the substrate integrated waveguide coupler, and having a preset section of the pipeline type via holes formed with at least one step.

However, objects of the present invention are not limited to the above, and other objects that have not been mentioned above will become clear to a person skilled in the art from the description below.

An exemplary embodiment of the present invention provides a substrate integrated waveguide coupler including: a substrate; an upper conducting plate applied to an upper portion of the substrate; a lower conducting plate applied to a lower portion of the substrate; two peripheral via holes disposed parallel to each other on both sides of the substrate, respectively, and being of a pipeline type electrically connecting the upper conducting plate and the lower conducting plate to each other; and an inner via hole disposed between the two peripheral via holes, and having a center thereof separated by a preset distance and forming a short slot functioning to couple input signals.

The peripheral via holes may be formed of the pipeline type at both sides of the substrate, respectively, and may have a cross section that is square or rectangular.

The via holes may include an impedance matching portion formed of one step being as large as a preset size such that a thickness of a preset section adjacent to the short slot becomes greater in an inward direction, the impedance matching portion matching impedance according to a frequency to be designed.

The impedance matching portion may be formed at the preset section adjacent to the short slot and have a length and a distance thereof that vary according to frequency.

The short slot may function to couple input signals, and a signal amount to be coupled may be changed according to a size of the short slot.

A propagation mode suitable for a frequency bandwidth to be designed may be determined according to a gap between the peripheral via holes and the inner via hole.

The via holes may include an impedance matching portion formed of a plurality of steps being as large as a preset size such that a thickness of a preset section adjacent to the short slot becomes greater in an inward direction, the impedance matching portion matching impedance according to a frequency to be designed.

The impedance matching portion may be formed at the preset section adjacent to the short slot and have a length and a distance thereof that vary according to frequency.

The short slot may function to couple input signals, and a signal amount to be coupled may be changed according to a size of the short slot.

A propagation mode suitable for a frequency bandwidth to be designed may be determined according to a gap between the peripheral via holes and the inner via hole.

According to exemplary embodiments of the present invention, it is possible to form pipeline type via holes to be disposed mutually parallel to each other at both sides of a substrate integrated waveguide coupler, and form a preset section of the pipeline type via holes with at least one step, in order to reduce a signal leak between the cylindrical via holes and reduce transmission loss.

According to exemplary embodiments of the present invention, it is possible to form pipeline type via holes to be disposed mutually parallel to each other at both sides of a substrate integrated waveguide coupler, and form a preset section of the pipeline type via holes with at least one step, in order to manufacture a fine impedance integrated structure because the structure is one that can be machine processed.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating the structure of a substrate integrated waveguide according to the related art.

FIG. 2 is a diagram illustrating the structure of a substrate integrated waveguide according to an exemplary embodiment of the present invention.

FIG. 3 is a first diagram illustrating the structure of a substrate integrated waveguide coupler according to an exemplary embodiment of the present invention.

FIG. 4 is a diagram for illustrating design variables for the substrate integrated waveguide coupler in FIG. 3.

FIG. 5 is a first diagram illustrating analyzed electromagnetic field results for the substrate integrated waveguide coupler in FIG. 3.

FIG. 6 is a second diagram illustrating analyzed electromagnetic field results for the substrate integrated waveguide coupler illustrated in FIG. 4.

FIG. 7 is a third diagram illustrating analyzed electromagnetic field results for the substrate integrated waveguide coupler illustrated in FIG. 4.

FIG. 8 is a second diagram illustrating the structure of a substrate integrated waveguide coupler according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

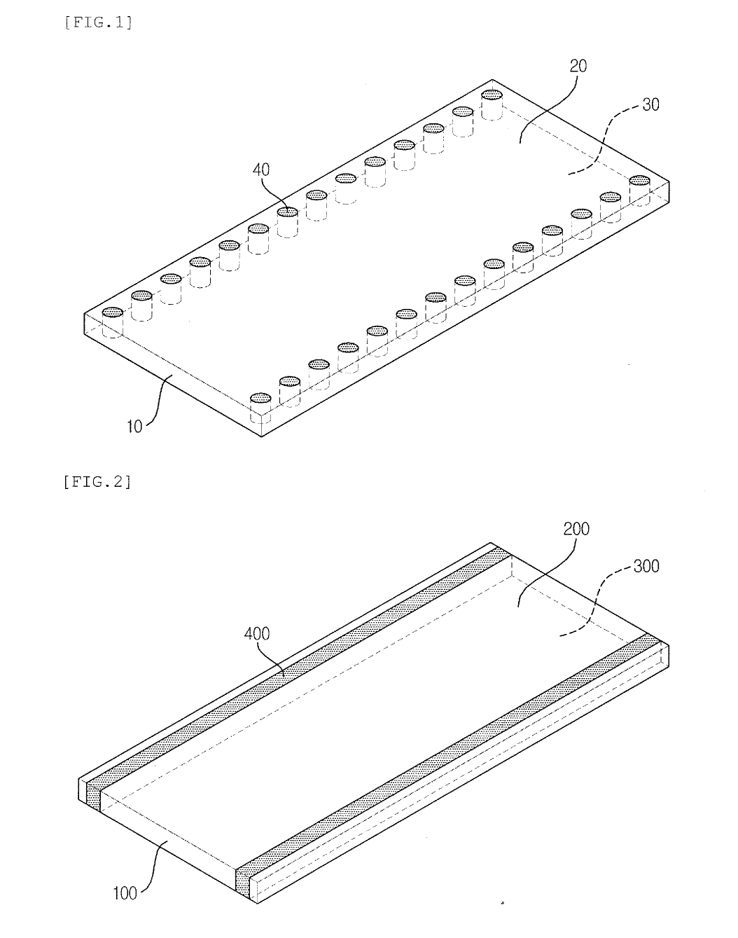

Hereinafter, a substrate integrated waveguide coupler according to exemplary embodiments of the present invention will be described in detail with reference to the accompanying drawings, FIGS. 2 to 8. The detailed description will focus on elements required for the understanding of the operation and effects according to the present invention.

Particularly, the present invention presents a novel structure having pipeline type via holes formed to be disposed mutually parallel to each other at both sides of the substrate integrated waveguide coupler, and having a preset section of the pipeline type via holes formed with at least one step.

FIG. 2 is a diagram illustrating the structure of a substrate integrated waveguide according to an exemplary embodiment of the present invention.

Referring to FIG. 2, a substrate integrated waveguide according to the present invention may be configured to include a substrate 100, an upper conducting plate 200, a lower conducting plate 300, and via holes 400.

The substrate 100 is formed as a dielectric substrate, and may have the upper conducting plate 200 applied on the top surface thereof and the lower conducting plate 300 applied on the bottom surface thereof.

The via holes 400 are disposed parallel to each other on both sides of the substrate 100, and may electrically connect the upper conducting plate 200 and the lower conducting plate 300. These via holes 400 may be formed, for example, as a pipeline type to block the leakage of signals to the outside.

Here, the via holes 400 may have a sectional shape that is square and rectangular.

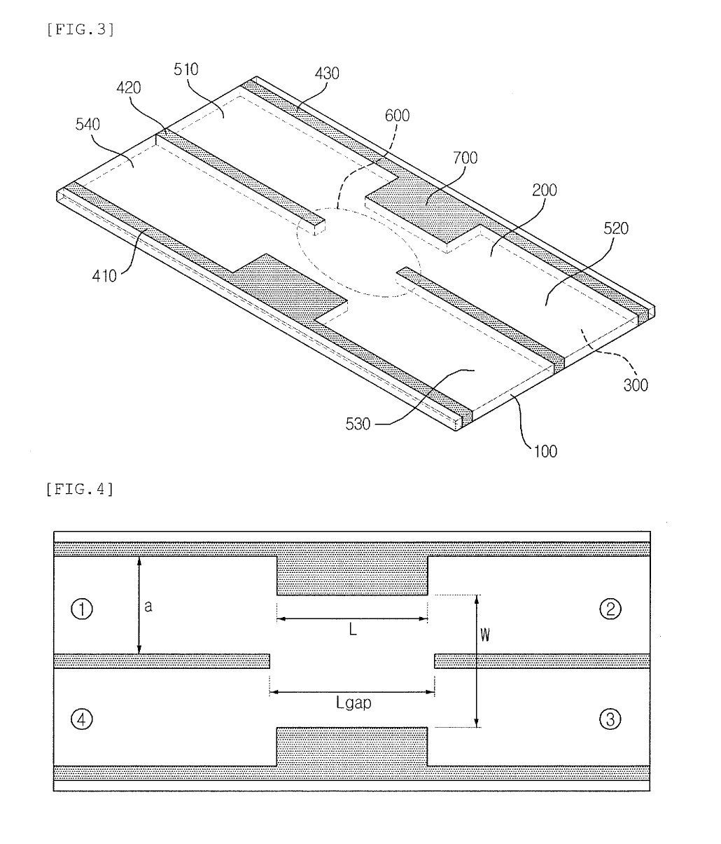

FIG. 3 is a first diagram illustrating the structure of a substrate integrated waveguide coupler according to an exemplary embodiment of the present invention.

Referring to FIG. 3, a short slot coupled to a substrate integrated waveguide according to the present invention is used to distribute one input signal or couple two input signals.

A substrate integrated waveguide coupler may be configured to include a first peripheral via hole 410, an inner via hole 420, a second peripheral via hole 430, an input terminal 510, a through terminal 520, a coupling terminal 530, an isolating terminal 540, a short slot 600, and an impedance matching portion 700.

The first peripheral via hole 410, the inner via hole 420, and the second peripheral via hole 430 may be disposed parallel to each other. The first peripheral via hole 410 and the second peripheral via hole 430 are disposed on both sides of the substrate integrated waveguide coupler, and the inner via hole 420 is disposed at the center of the substrate integrated waveguide coupler.

The inner via hole 420 is disposed at the center of the substrate integrated waveguide coupler, and the center thereof is separated by a preset distance to form the short slot 600 for coupling signals.

Here, the size of the short slot 600 may be made different according to the quantity of signals to be coupled.

A step may be formed of a preset size toward an inner direction of the thickness of a preset section adjacent to the short slot 600 where the first peripheral via hole 410 and the second peripheral via hole 430 are disposed on both sides of the substrate integrated waveguide coupler, so as to provide the impedance matching portion 700 for matching impedance according to frequency.

Here, the size of the impedance matching portion 700, formed to correspond to each of the first peripheral via hole 410 and the second peripheral via hole 430, may be formed, for example, with the same length, width, etc.

Also, the size of the impedance matching portion 700 may be changed according to the frequency to be designed.

A signal input by the input terminal 510 from the short slot 600 may be divided in a certain ratio by the impedance matching portion 700 and outputted to the through terminal 520 and the coupling terminal 530.

Here, the signal is not output to the isolating terminal 540 through impedance matching. That is, when impedance matching is properly implemented, no signal is output to the isolating terminal 540.

FIG. 4 is a diagram for illustrating design variables for the substrate integrated waveguide coupler in FIG. 3.

Referring to FIG. 4, the design variables for a substrate integrated waveguide coupler according to the present invention may include a length “a” between via holes, a length “Lgap” of the short slot, a length “L” and a width “W” of the inductance matching portion.

1) The length a between via holes may determine a propagation mode which standardizes or characterizes the qualities of a signal travelling within the substrate integrated waveguide. Here, the propagation mode may represent a TE (Transverse Electric Field/Wave) mode and a TM (Transverse Magnetic Field/Wave) mode.

2) The length Lgap of the short slot may determine the coupling amount of a signal.

3) The length L and the distance W of the impedance matching portion may match impedance according to a frequency to be designed.

The substrate integrated waveguide coupler is structure having a rectangular cross section, a conductor on the outside, and filled with a dielectric inside. Thus, without a dielectric, the coupler would be the same as a typical older rectangular waveguide. That is, the propagation mode and frequency blocking characteristics of the substrate integrated waveguide are the same as those of a basic older waveguide, and a basic propagation mode is also the same, as a TE₁₀ mode.

The blocked frequency of this substrate integrated waveguide may be determined with the following [Equation 1].

$${f}_{c , mn} = \frac{1}{2 π \sqrt{μɛ}} \sqrt{{( \frac{m π}{a} )}^{2} + {( \frac{n π}{b} )}^{2}} \qquad [ Equation 1 ]$$

Here, “a” and “b” are the lengths of the long axis and the short axis of the cross section of an older waveguide, and “∈” and “μ” represent dielectric permittivity and permeability.

A blocked frequency for TE₁₀ mode that is a basic propagation mode may be determined through the following [Equation 2].

$${f}_{c , 10} = \frac{1}{2 a \sqrt{μɛ}} \qquad [ Equation 2 ]$$

Thus, by controlling the long axis length “a” within the substrate integrated waveguide coupler, a travelling wave mode or a propagation mode suitable for a frequency bandwidth to be designed may be determined.

Also, the size of the short slot Lgap may control the coupling amount of the coupler. For example, if the size of the short slot Lgap is small, assuming that power is input to a first terminal, more power is distributed to a second terminal than a third terminal. Conversely, if the size of the short slot Lgap becomes larger, more power is coupled to the third terminal than the second terminal.

Further, the size of the length L and distance W of the impedance matching portion perform the function of matching impedance to the frequency used, and may make the bandwidth wide by using a suitable form.

FIG. 5 is a first diagram illustrating analyzed electromagnetic field results for the substrate integrated waveguide coupler in FIG. 4.

Referring to FIG. 5, a 3 dB substrate integrated waveguide coupler according to an exemplary embodiment of the present invention is embodied, the long axis length “a” within the substrate integrated waveguide coupler was designed to be 7.46 mm, and the analyzed electromagnetic field results for the thus-embodied substrate integrated waveguide coupler are shown.

In particular, the substrate integrated waveguide coupler shows a transmission loss of about 1 dB at 21 GHz and a good reflective loss of 30 dB or greater and good isolation.

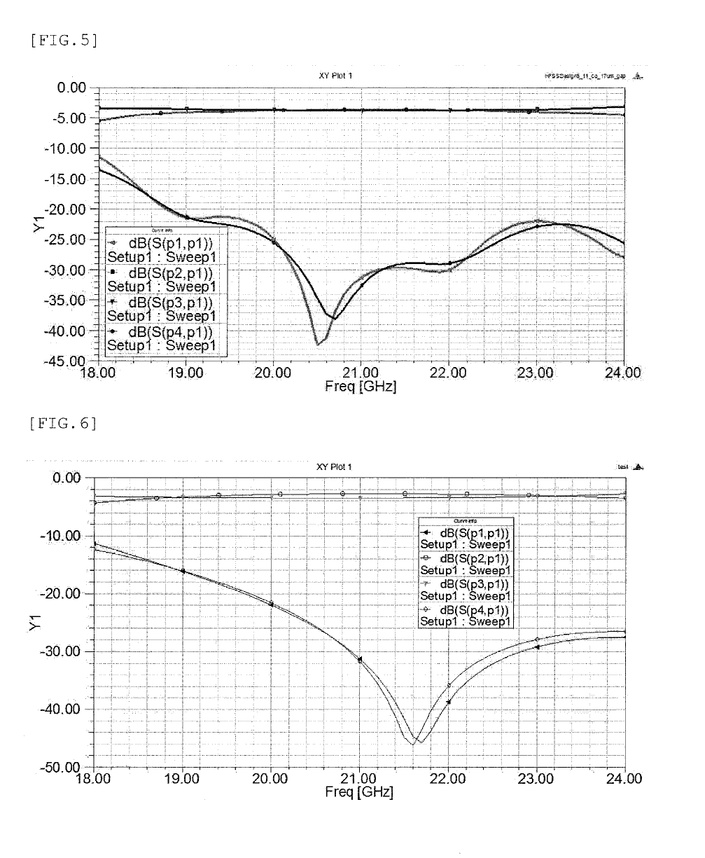

FIG. 6 is a second diagram illustrating analyzed electromagnetic field results for the substrate integrated waveguide coupler illustrated in FIG. 4.

Referring to FIG. 6, a 3 dB substrate integrated waveguide coupler according to an exemplary embodiment of the present invention is embodied, the size of the short slot length Lgap within the substrate integrated waveguide coupler was designed to be 8.9 mm, and the analyzed electromagnetic field results for the thus-embodied substrate integrated waveguide coupler are shown.

In particular, it is apparent that a greater amount of power is coupled to the through terminal 2 in the coupler.

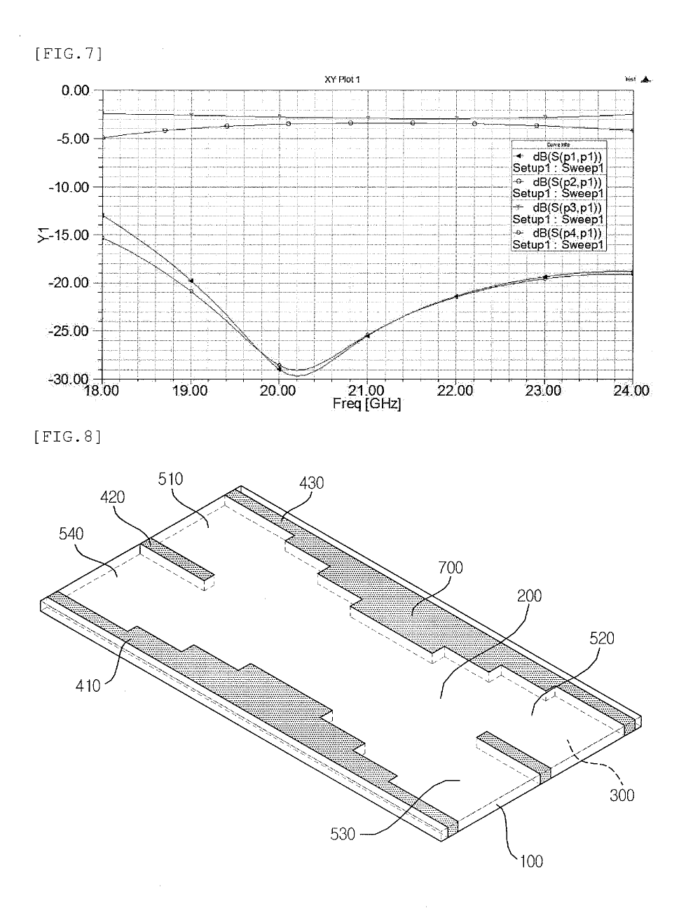

FIG. 7 is a third diagram illustrating analyzed electromagnetic field results for the substrate integrated waveguide coupler illustrated in FIG. 4.

Referring to FIG. 7, a 3 dB substrate integrated waveguide coupler according to an exemplary embodiment of the present invention is embodied, the size of the short slot length Lgap within the substrate integrated waveguide coupler was designed to be 9.3 mm, and the analyzed electromagnetic field results for the thus-embodied substrate integrated waveguide coupler are shown.

In particular, it is apparent that a greater amount of power is coupled to the through terminal 3 in the coupler.

FIG. 8 is a second diagram illustrating the structure of a substrate integrated waveguide coupler according to an exemplary embodiment of the present invention.

Referring to FIG. 8, while the substrate integrated waveguide coupler according to the present exemplary embodiment is the same in terms of function as the substrate integrated waveguide coupler described with reference to FIG. 3, a plurality of steps may be formed of a preset size toward an inner direction of the thickness of a preset section adjacent to the short slot 600 where the first peripheral via hole 410 and the second peripheral via hole 430 are disposed on both sides of the coupler, so as to provide the impedance matching portion 700 for matching impedance according to frequency.

Here, the step of the impedance matching portion 700 may be formed as a plurality of steps according to need.

Meanwhile, by mentioning that all constituent elements constituting exemplary embodiments of the present invention described above are coupled or are coupled and operate as one, the present invention is not limited to such exemplary embodiments. That is, all constituent elements may be selectively coupled and operated as one or more, as long the constituent elements fall within the scope of the object of the present invention.

Also, all terminology including technical or scientific terms shall have the same meaning as generally understood by a person having ordinary skill in the art to which the present invention pertains, provided that said terminology has not been defined otherwise in the detailed description. Terms that are generally used such as previously defined terminology shall be interpreted as having the same meaning as that set forth in the related art, and shall not be interpreted as having an ideal or excessive formal meaning, unless otherwise clearly defined in the present invention.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A substrate integrated waveguide coupler comprising:
a substrate;
an upper conducting plate applied to an upper portion of the substrate;
a lower conducting plate applied to a lower portion of the substrate;
two peripheral via holes disposed parallel to each other on both sides of the substrate, respectively, and being of a pipeline type electrically connecting the upper conducting plate and the lower conducting plate to each other; and
an inner via hole disposed between the two peripheral via holes, and having a center thereof separated by a preset distance and forming a short slot functioning to couple input signals.

2. The substrate integrated waveguide coupler of claim 1, wherein the peripheral via holes are formed of the pipeline type at both sides of the substrate, respectively, and have a cross section that is square or rectangular.

3. The substrate integrated waveguide coupler of claim 1, wherein the via holes include an impedance matching portion formed of one step being as large as a preset size such that a thickness of a preset section adjacent to the short slot becomes greater in an inward direction, the impedance matching portion matching impedance according to a frequency to be designed.

4. The substrate integrated waveguide coupler of claim 3, wherein the impedance matching portion is formed at the preset section adjacent to the short slot and has a length and a distance thereof that vary according to frequency.

5. The substrate integrated waveguide coupler of claim 3, wherein the short slot functions to couple input signals, and a signal amount to be coupled is changed according to a size of the short slot.

6. The substrate integrated waveguide coupler of claim 1, wherein a propagation mode suitable for a frequency bandwidth to be designed is determined according to a gap between the peripheral via holes and the inner via hole.

7. The substrate integrated waveguide coupler of claim 1, wherein the via holes include an impedance matching portion formed of a plurality of steps being as large as a preset size such that a thickness of a preset section adjacent to the short slot becomes greater in an inward direction, the impedance matching portion matching impedance according to a frequency to be designed.

8. The substrate integrated waveguide coupler of claim 7, wherein the impedance matching portion is formed at the preset section adjacent to the short slot and has a length and a distance thereof that vary according to frequency.

9. The substrate integrated waveguide coupler of claim 7, wherein the short slot functions to couple input signals, and a signal amount to be coupled is changed according to a size of the short slot.

10. The substrate integrated waveguide coupler of claim 7, wherein a propagation mode suitable for a frequency bandwidth to be designed is determined according to a gap between the peripheral via holes and the inner via hole.
